(19) United States
(12) Patent Application Publication
(10) Pub. No.: US 2006/0007758 A1
(43) Pub. Date: Jan. 12, 2006

(54) Method and apparatus for setting CAS latency and frequency of heterogenous memories

(75) Inventor: Cheol-Ho Lee, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/175,180

(22) Filed: Jul. 7, 2005

(30) Foreign Application Priority Data
Jul. 12, 2004 (KR) 10-2004-0054045

(51) Int. Cl. G11C 7/00

(52) U.S. Cl. 365/193

(57) ABSTRACT

A method and apparatus for setting column address strobe (CAS) latency and frequency for heterogeneous memories are provided. The method includes obtaining setting information related to CAS latencies and frequencies supported by two or more memories, and comparing the CAS latencies supported by the memories with one another and setting a highest frequency among the frequencies that all of the memories have in common as a common frequency for the memories if the memories have one or more CAS latencies in common.

### CROSS-REFERENCE TO RELATED APPLICATION

This application claims the benefit under 35 U.S.C. 119(a) of Korean Patent Application No. 10-2004-0054045 filed on Jul. 12, 2004 in the Korean Intellectual Property Office, the disclosure of which is incorporated herein by reference in its entirety.

### BACKGROUND OF THE INVENTION

1. Field of the Invention

The present invention relates to a method and an apparatus for setting the column address strobe (CAS) latency and frequency of heterogeneous memories.

2. Description of the Related Art

Memories can include the random access memory (RAM) of a system such as a computer. A system stores temporary commands and data necessary for performing its operations in RAM. A central processing unit (CPU), which controls the system, can quickly access the temporary commands and data stored in the RAM.

The speed of writing data to or reading data from a memory affects the operating speed of the entire system, and the storage capacity of the memory affects the throughput of the entire system. Accordingly, various memory techniques have been developed in an effort to increase the storage capacity and the speed of writing data to or reading data from memory.

A single in-line memory module (SIMM) and a dual in-line memory module (DIMM) provide slots in which memory can be installed. A SIMM and DIMM are each is a small-sized printed circuit board (PCB) on which one or more RAM chips are installed, and which has a plurality of pins connected to a motherboard of a computer. The SIMM and DIMM modules are distinguished by the signal lines that connect the module to the system. That is to say, the SIMM and DIMM modules have a different number and structure of pins (connectors).

A synchronous dynamic random access memory (SDRAM) synchronizes an input signal of a memory chip with an output signal of the memory chip using a clock signal. The clock signal is synchronized with a CPU clock signal and thus can synchronize the timing of the memory chip with the timing of a CPU. SDRAM reduces the time required for executing a command and transmitting data, thereby enhancing the performance of a computer. A CPU can access SDRAM at about a 25% higher speed than it can access extended data out (EDO) memory.

Data can be read from a double data rate (DDR) SDRAM in response to both a rising edge and a falling edge of a system clock signal. Thus, DDR SDRAM can double the data access rate of a memory chip. Accordingly, when the internal memory clock speed of a system is 100 MHz, DDR SDRAM can achieve a memory clock speed of 200 MHz.

In order to write data to or read data from memory, a memory address must be designated in advance, a process which is called addressing. A bus receives a row address, which designates a predetermined portion of memory, separately from a column address, which designates the predetermined portion of the memory. The units of a system, including a CPU, transmit a short signal called strobe before transmitting data to one another in order to be synchronized with one another. A strobe signal for a row address is called a row address strobe (RAS) signal, and a strobe signal for a column address is called a column address strobe (CAS) signal.

RAS or CAS time considerably affects the read/write performance of memory. Particularly, CAS latency is the number of clock pulses required to transmit a CAS signal. The higher the CAS latency a memory has, the more time it takes to read and write data to and from the memory. However, in a case where different types of memory each having different CAS latencies and clock speeds are installed together in the DIMM slots of a system, the heterogeneous memory needs to be adjusted to have the same CAS latency and clock speed. As a result, however, some of the heterogeneous memory may be set to a lower CAS latency and a lower clock speed and thus may not operate at full capacity. Accordingly, it is necessary to appropriately control the CAS latency and clock speed settings.

### SUMMARY OF THE INVENTION

The present invention provides a method and an apparatus for setting column address strobe (CAS) latency and frequency for two or more heterogeneous memories, which can enhance the operating speeds of the memories.

The present invention also provides a method and an apparatus for setting CAS latency and frequency for two or more heterogeneous memories, which can enhance the extendibility and data processing speed of a system.

The above stated objects as well as other objects, features and advantages, of the present invention will become clear to those skilled in the art upon review of the following description.

According to an aspect of the present invention, there is provided a method of setting CAS latency and frequency for heterogeneous memories comprising obtaining setting information related to CAS latencies and frequencies supported by two or more memories; and comparing the CAS latencies supported by the memories with one another and setting a highest frequency from among the common frequencies as a common frequency for the memories if the memories have one or more CAS latencies in common.

According to another aspect of the present invention, there is provided a system comprising two or more memories, which store information and to and from which data is written and read, respectively; a system driving unit which performs setting for the memories, and a memory controller, which controls the memories, wherein if the memories have one or more CAS latencies in common, the system driving unit sets a highest frequency from among the common frequencies as a common frequency for the memories, and the memory controller controls the memories to operate at this common frequency.

### BRIEF DESCRIPTION OF THE DRAWINGS

The above and other features and advantages of the present invention will become more apparent by describing in detail preferred embodiments thereof with reference to the attached drawings in which:

FIG. 1 is a diagram illustrating the relationship between a memory controller and memories according to an exemplary embodiment of the present invention;

FIG. 2 is a diagram illustrating a mode register setting according to an exemplary embodiment of the present invention;

FIG. 3 is a flowchart illustrating a method of setting the column address strobe (CAS) latency and frequency for two memories according to an exemplary embodiment of the present invention;

FIG. 4 is a flowchart illustrating a method of setting the CAS latency and frequency of heterogeneous memories according to an exemplary embodiment of the present invention;

FIG. 5 is a timing diagram for comparing a method of setting the CAS latency and frequency of heterogeneous memories according to an exemplary embodiment of the present invention with a conventional method for doing the same;

FIG. 6 illustrates tables for comparing the performance of a method of setting the CAS latency and frequency for two different memories according to an exemplary embodiment of the present invention with the performance of a conventional method;

FIG. 7 illustrates tables for comparing the performance of a method of setting the CAS latency and frequency for two different memories according to an exemplary embodiment of the present invention with the performance of a conventional method;

FIG. 8 illustrates tables for comparing the performance of a method of setting the CAS latency and frequency for three different memories according to an exemplary embodiment of the present invention with the performance of a conventional method; and

FIG. 9 is a block diagram illustrating an apparatus for setting the CAS latency and frequency for a heterogeneous memory according to an exemplary embodiment of the present invention.

Throughout the drawings, the same or similar elements, features and structures are represented by the same reference numerals.

### DETAILED DESCRIPTION OF EXEMPLARY EMBODIMENTS

The present invention will now be described more fully with reference to the accompanying drawings, in which embodiments of the invention are shown.

Terms that are frequently mentioned in this disclosure will be described in the following.

CAS Latency

A system issues a request for a memory address before writing data to or reading data from the memory by transmitting a column address strobe (CAS) signal to the memory. CAS latency indicates the amount of delay time between the moment when the system sends the CAS signal to memory and the moment when the system writes data to or reads data from memory. CAS latency is related to a clock signal. If CAS latency is 3, it takes three times the clock period for the system to write data to or read data from the memory after transmitting the CAS signal to the memory. For example, if one clock cycle is 5 ns (1 ns=10⁻⁹ sec) and CAS latency is 3, it takes 15 ns for the system to write data to or read data from memory.

Serial Presence Detect (SPD) Device

A SPD device is a small 8-pin electrically erasable programmable read-only memory (EEPROM). A SPD device records the storage capacity, operating speed, voltage, and the numbers of address columns and rows of the synchronous dynamic random access memory (SDRAM), and helps a basic input output system (BIOS) to optimize the timing of the SDRAM.

System

A system may be any device that needs memory, for example, a computer. The embodiments of the present invention will now be described taking a computer as an example of the system because memory technologies are most widely used in computers. However, the present invention is also applicable to any devices that need memory such as a communication system, a home appliance, and a digital broadcast device (e.g., a set-top box).

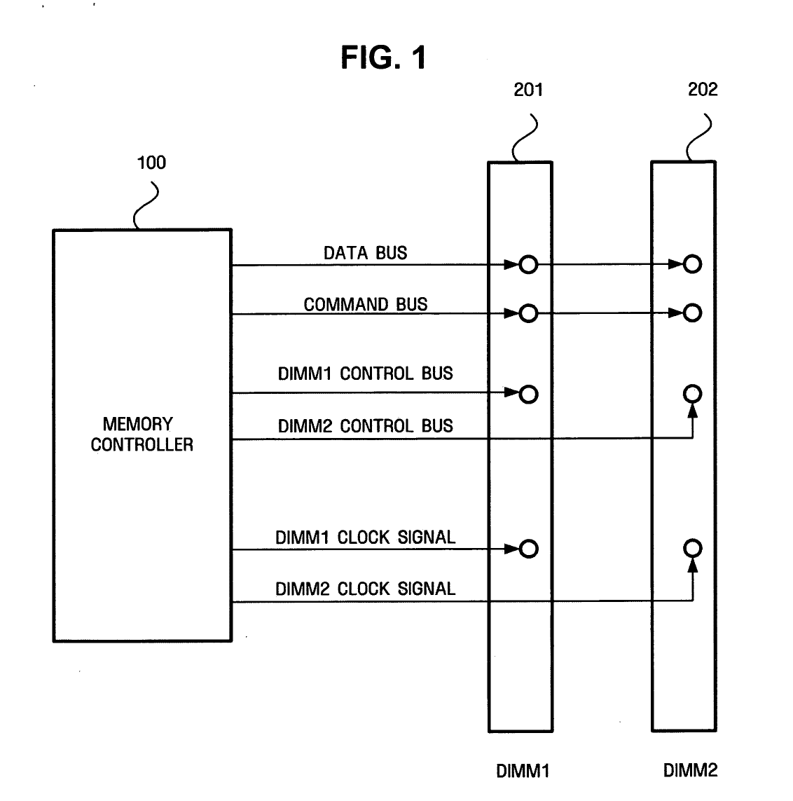

FIG. 1 is a diagram illustrating the relationship between a memory controller 100 and memories 201 and 202 according to an exemplary embodiment of the present invention. Referring to FIG. 1, the memory controller 100 receives a write or read command from an external device. That is, in response to the received write or read command, the memory controller 100 prepares a data bus for writing data to or read data from each of the memories 201 and 202, and has a command bus forward the received write or read command.

In order to perform a read or write operation, the memory controller 100 needs a control bus for transmitting memory addresses and commands, via which information required for designating a column address and a row address of a predetermined portion of each of the memories 201 and 202 where data is to be stored and information required for controlling the writing/reading of data to/from each of the memories 201 and 202 in units of pages are transmitted.

A dual in-line memory module 1 (DIMM1) clock signal and a DIMM2 clock signal are respectively used to control the operations of the memories 201 and 202. The write or read command and a control command are transmitted in response to a clock signal having a cycle of, for example, a few ns. A memory having a 5 ns clock cycle has a frequency of 200 MHz. A typical memory operates in response to either a rising edge or a falling edge of a clock signal. Recently, double data rate (DDR) memory that operates in response to both a rising edge and a falling edge of a clock signal has been developed. DDR memory having a 5 ns clock cycle operates at a frequency of 400 MHz.

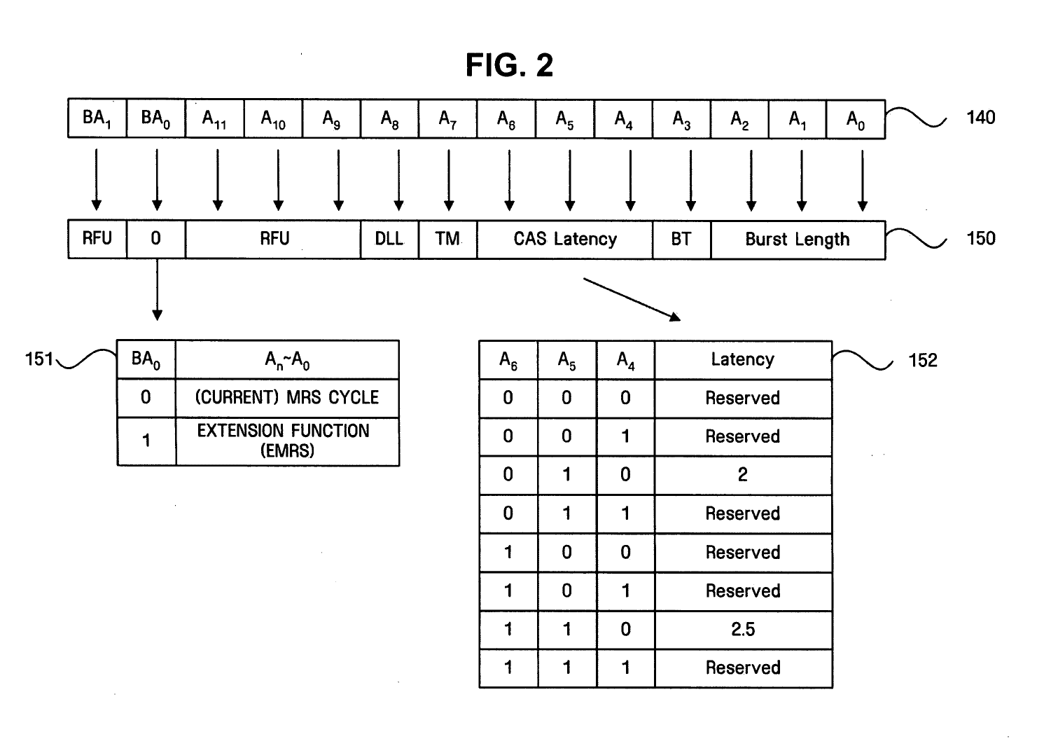

FIG. 2 is a diagram illustrating a mode register setting required for setting a memory according to an exemplary embodiment of the present invention. Referring to FIG. 2, in order to control the memory, a memory controller must operate by considering characteristics of the memory. Therefore, the memory controller reads information about the memory from a SPD device and registers settings for the memory; a process that is called mode register setting. A register 150 can store mode settings such as cycle time 151, CAS latency 152, and burst length. In a burst mode, which is a high-speed data transfer mode, when a processor issues a request for an address, one block of data (e.g., a series of consecutive addresses) is automatically fetched, and thus, a processor can transmit data by designating a current address from this block of addresses. Once memory information, such as the CAS latency 152 and the cycle time 151, is set through mode register setting, the memory controller writes data to or reads data from the memory with reference to this information. For example, if the CAS latency 152 is set to a value of 3, the memory controller considers that the memory has a CAS latency of 3.

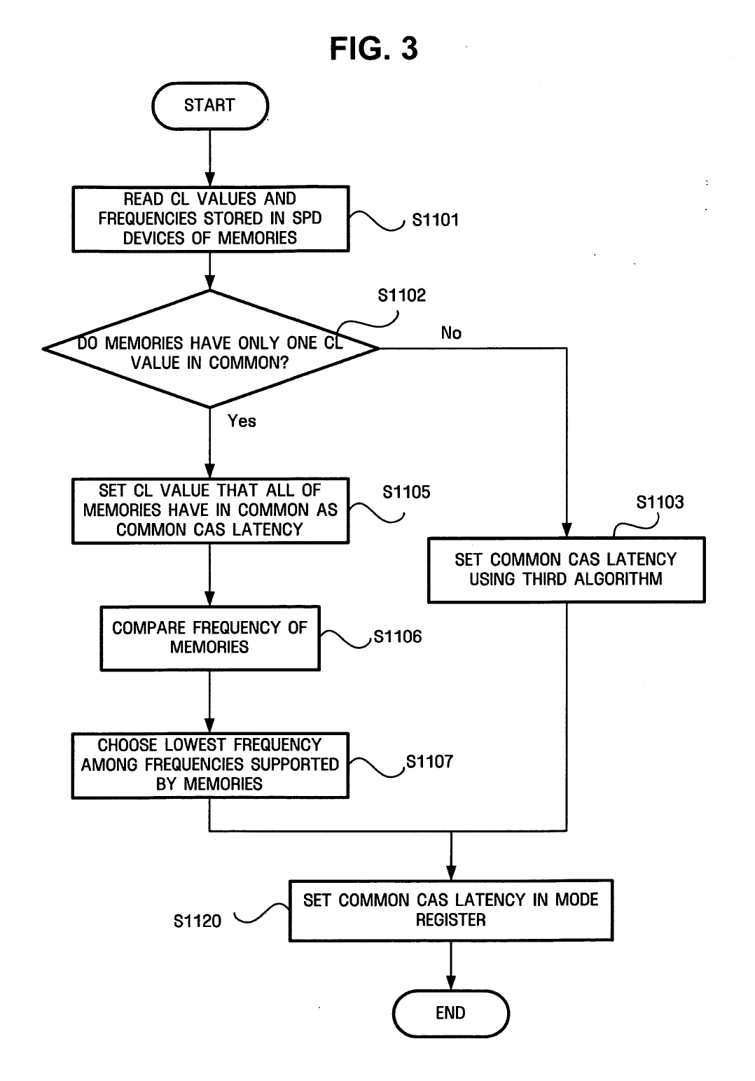

FIG. 3 is a flowchart illustrating a method of setting the CAS latency and frequency for two memories based on a result of comparing the CAS latency values (hereinafter referred to as CL values) and frequencies supported by the memories.

Referring to FIG. 3, in operation S1101, the CL values and the frequencies are read from an SPD device coupled to each of the memories. If the memories are different, CL values and frequencies that they support may differ. In operation S1102, the read CL values are compared with one another. If the two memories have only one CL value in common, the method proceeds to operation S1105. In operation S1103, if the two memories have all of the CL values in common or if the two memories have no CL value in common, a common CAS latency for the two memories is determined using a third algorithm. In operation S1105, if the two memories have only one CL value in common, this CL value is chosen as the common CAS latency. In operation S1106, the frequencies of the two memories are compared with one another. In operation S1107, the lowest frequency of the frequencies supported by the two memories is chosen as the common frequency because both memories can operate at this frequency. In operation S1120, this common frequency is stored in a mode register. Thereafter, a memory controller performs a write or read operation on each of the memories by driving each of the memories at the common CAS latency and frequency.

Operations S1105 through 107 will now be described in further detail with reference to Table 1.

TABLE 1
CL Values and Cycle Times of DDR Memories

| | | | Cycle time when CL | Cycle time when CL |
|---|---|---|---|---|
| Memory Model | CL Values | | value is high | value is low |
| Memory 1 | 2.5 | 3 | 6.0 ns | 5.0 ns |
| (DDR) | | | | |
| Memory 2 | 2 | 2.5 | 7.5 ns | 5.0 ns |
| (DDR) | | | | |

In Table 1, cycle time indicates the length of the clock cycle, and the frequency of the clock signal is the inverse of this cycle time. For example, if cycle time is 5.0 ns, the frequency of the clock signal is 200 MHz (=1000/5.0 MHz). Since memories 1 and 2 are DDR memories, they can achieve two times the frequency of the clock signal, i.e., a frequency of 400 MHz.

Referring to Table 1, the CL value that both of memories 1 and 2 have in common is 2.5. Thus, in operation S1105, memories 1 and 2 are set to a CL value of 2.5. As a result, in operation S1106, the operating frequency of memory 1 is automatically determined to be 333 MHz (6.0 ns), and the operating frequency of memory 2 is automatically determined to be 400 MHz (5.0 ns). In operation S1107, a frequency of 333 MHz is chosen as a common frequency for memories 1 and 2 because it is the lower of the two frequencies corresponding to a CAS latency of 2.5. In operation S1120, both memories 1 and 2 are set to a CL value of 2.5 and a frequency of 333 MHz.

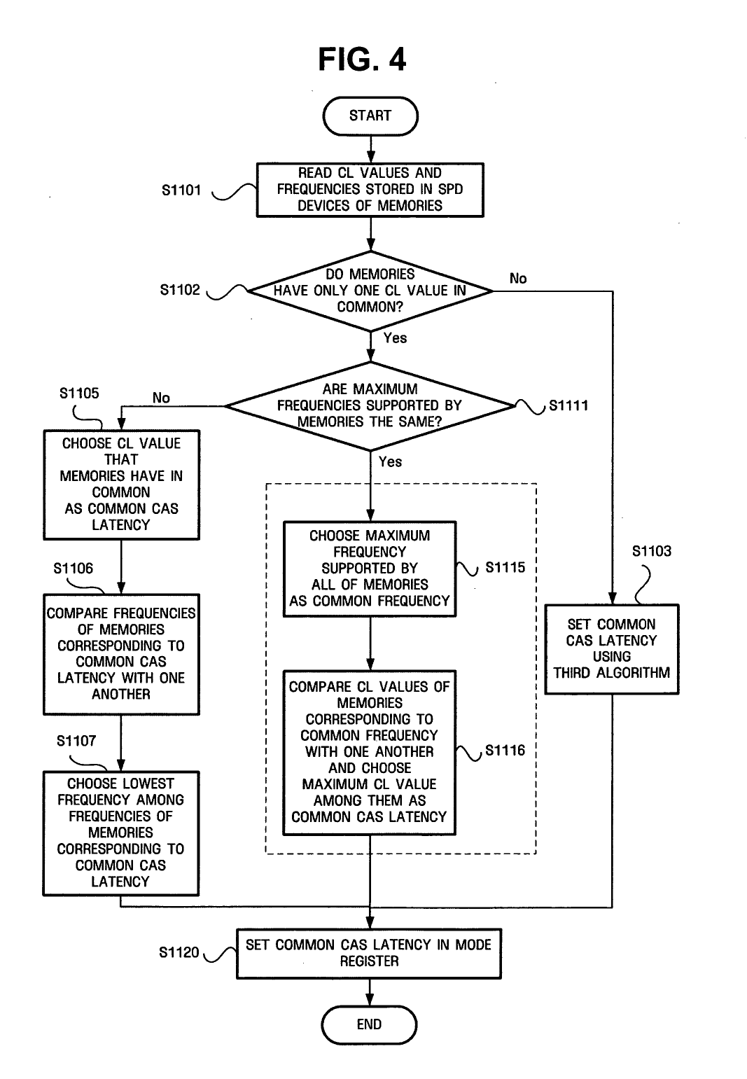

As described above, memories 1 and 2 are all set to a frequency of 333 MHz even though they can operate at a frequency of up to 400 MHz. As such, they do not operate at full capacity. The present invention, however, provides a method of setting the CAS latency and frequency of heterogeneous memories enabling these memories to operate at full capacity. This is described in detail in the following with reference to FIG. 4.

FIG. 4 is a flowchart illustrating a method of setting the CAS latency and frequency of two different memories according to an exemplary embodiment of the present invention. Operations S1101 through S1107 and S1120 of FIG. 4 are the same as operations S1101 through S1107 and S1120 of FIG. 3, and a detailed explanation thereof is omitted here. The method of FIG. 4 is different from the method of FIG. 3 in that the common frequency is first set and then the common CAS latency is set.

Referring to FIG. 4, if the two memories have one CL value in common in operation S1102, it is determined whether the maximum frequency supported by one of the two memories is equal to the maximum frequency supported by the other memory in operation S1111. If the maximum frequencies supported by the two memories are not the same, a CL value that both memories have in common is chosen as a common CAS latency for the two memories in operation S1105, and the lowest frequency among the frequencies that both memories have in common is chosen as the common frequency in operations S106 and S107.

However, if the maximum frequencies supported by the two memories are the same in operation S1111, this maximum frequency is chosen as the common frequency in operation S1115. In operation S1116, the two memories are set to the respective CL values corresponding to the common frequency, and the highest CL value is chosen as the common CAS latency. In operation S1120, the common CAS latency is set in the mode register. The effects of the method of FIG. 4 will be described in detail with reference to Table 1.

Referring to Table 1, the maximum frequency (i.e., 5.0 ns, 400 MHz) supported by memory 1 is the same as the maximum frequency supported by memory 2. Thus, in operation S1115 of FIG. 4, a frequency of 400 MHz is set as the common frequency of memories 1 and 2. In memory 1 using frequency of 400 MHz, CL value can be 3, in memory 2 using frequency of 400 MHz, CL value can be 2.5, So, in operation S1116, the highest CL value is chosen as the common CAS latency. In operation S1120, mode register setting is complete by setting the common CAS latency. In short, the method of FIG. 4 provides a CL value of 3 and a cycle time of 5.0 ns (a frequency of 400 MHz) as the common CAS latency and the common cycle time, respectively, while the method of FIG. 3 provides a CL value of 2.5 and a cycle time of 6.0 (a frequency of 333 MHz) as the common CAS latency and the common cycle time, respectively. In other words, the method of FIG. 4 achieves a higher common CAS latency and a higher common frequency than the method of FIG. 3 and thus may appear to be more effective than the method of FIG. 3 in terms of setting the common frequency, but appears to be less effective than the method of FIG. 3 in terms of setting the common CAS latency. However, a high common CAS latency would not be absolute proof that the method of FIG. 4 is less effective than the method of FIG. 3 because CAS latency is not an absolute value but a multiple of the clock cycle, that is, actual delay time decreases with cycle time.

As described above, the method of FIG. 3 provides a CL value of 2.5 and a cycle time of 6.0 ns; this produces an actual delay time of 15 ns (=2.5×6.0 ns). However, the method of FIG. 4 provides a CL value of 3 and a cycle time of 5.0 ns, but the actual delay time (15 ns=3×5.0 ns) is the same as that of the method of FIG. 3.

In short, the method of FIG. 4 increases the common frequency of memories 1 and 2 from 333 MHz to 400 MHz without increasing actual delay time required for writing data to or reading data from each of memories 1 and 2 and thus considerably enhances the operating speeds of memories 1 and 2.

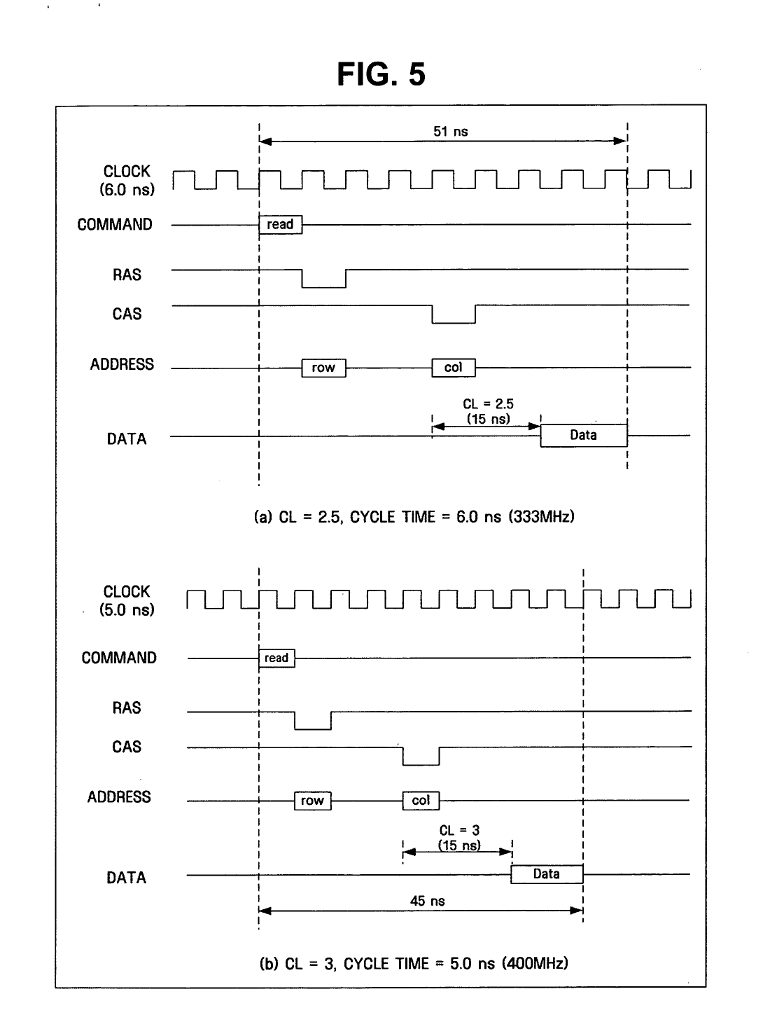

FIG. 5 is a timing diagram for comparing the performance of a method of setting the CAS latency and frequency of heterogeneous memories according to an exemplary embodiment of the present invention with the performance of a conventional method of setting the CAS latency and frequency for heterogeneous memories. Specifically, FIG. 5(a) illustrates the performance of a conventional method in a case where the CAS latency is set to a value of 2.5 and the frequency is set to 6.0 ns (333 MHz). Referring to FIG. 5(a), in response to a read command input via a command bus, a row address strobe (RAS) signal is input, and two cycles later (i.e., 12 ns later), a CAS signal is input so as to respectively determine a row address and a column address of the memory. Thereafter, since CAS latency is set to a value of 2.5, data is read from a predetermined portion of the memory designated by a combination of the row address and the column address 2.5 cycles (i.e., 15 ns) after the CAS signal is input. As a result, it takes a total of 51 ns to complete a read operation after the read command is input via the command bus.

FIG. 5(b) illustrates the performance of a method of setting the CAS latency and frequency of a heterogeneous memory according to an exemplary embodiment of the present invention in a case where the CAS latency is set to a value of 3 and the cycle time is set to 5.0 ns (400 MHz). Referring to FIG. 5(b), the address of a predetermined portion of a memory from which data is to be read in response to a read command input via a command bus is determined in the same manner as described above with reference to FIG. 5(a). Since CAS latency is set to a value of 3, data can be read from the memory three cycles (i.e., 15 ns) after the CAS signal is input. Accordingly, it takes a total of 45 ns to complete a read operation after the read command is input via the command bus. Therefore, the method of FIG. 5(b) takes at least 10% less time than the conventional method of FIG. 5(a) to complete a read operation.

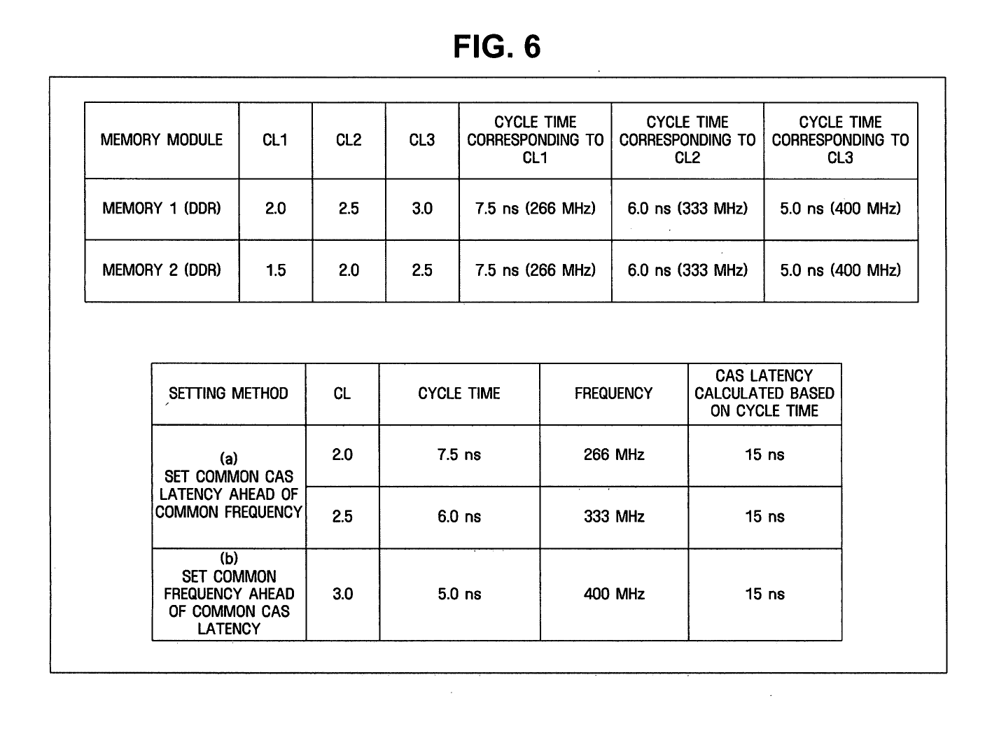

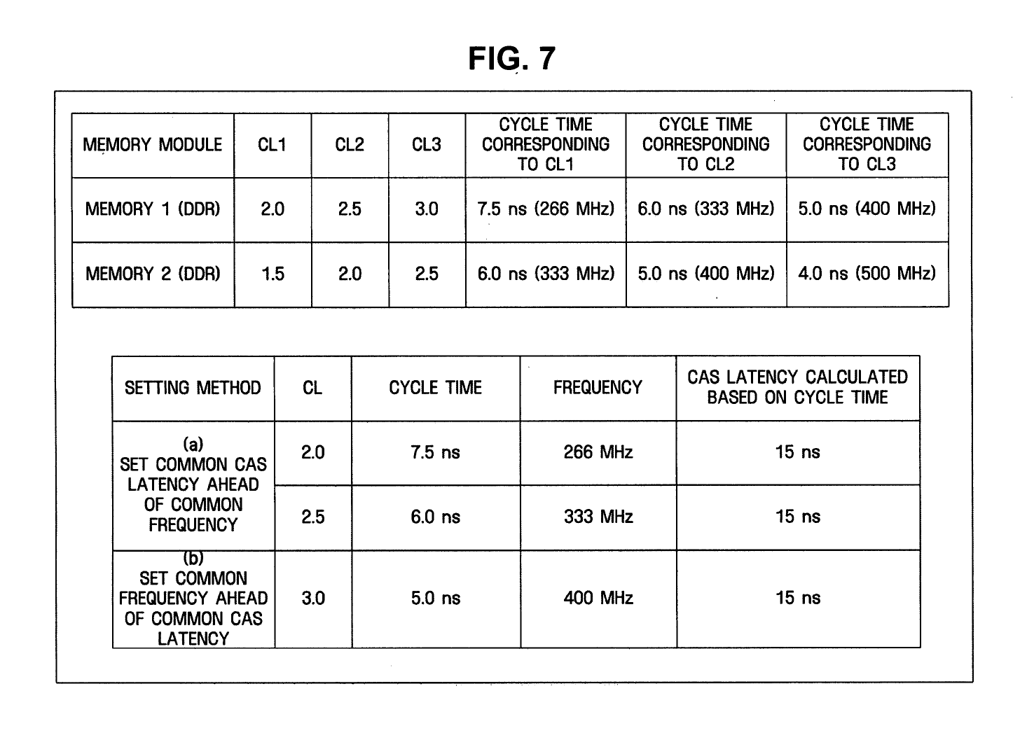

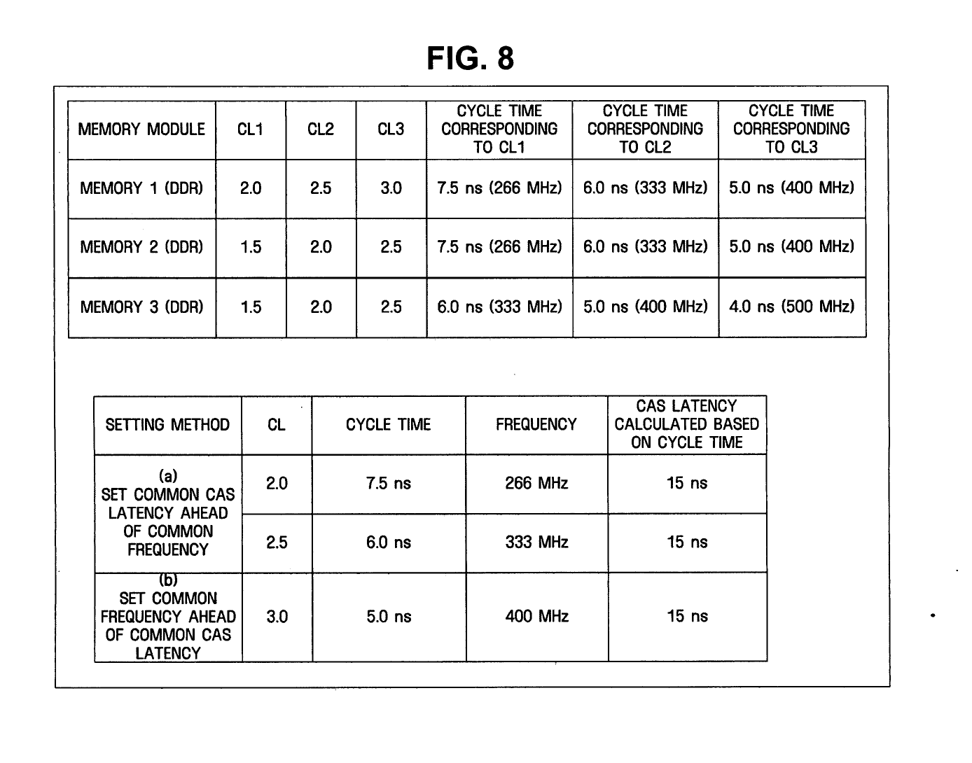

The methods of FIGS. 3 and 4 have been described above as being applicable to two memories each supporting two CAS latencies and two frequencies, but the present invention is not restricted thereto. FIGS. 6 and 7 are tables illustrating CAS latency and frequency settings for a heterogeneous memory supporting three CAS latencies and three frequencies according to exemplary embodiments of the present invention. FIG. 8 comprises tables illustrating CAS latency and frequency settings for a heterogeneous memory according to an exemplary embodiment of the present invention.

FIG. 6 illustrates tables for comparing the performance of a method of setting the CAS latency and frequency of two different memories according to an exemplary embodiment of the present invention with the performance of a conventional method of setting the CAS latency and frequency of two different memories. As described above, the frequency of DDR memory can be twice as high as that of conventional memory. Referring to FIG. 6, CAS latency, cycle time, and frequency settings and results of the conventional method for two different memories are shown in (a). The conventional method shown in (a) of FIG. 6 is the same as the method of FIG. 3 except that each of the memories 1 and 2 supports three CAS latencies rather than two. Thus, the description of the method of FIG. 3 is also applicable to the conventional method shown in (a) of FIG. 6. Unlike operation S1102 of the method of FIG. 3, in the conventional method shown in (a) of FIG. 6, it is determined whether memories 1 and 2 have one or more CL values in common, rather than whether they have only one CL value in common. Referring to FIG. 6, memories 1 and 2 have two CL values in common-2.0 and 2.5. If a CL value of 2.0 is set as the common CAS latency, memory 1 is set to a cycle time of 7.5 ns (266 MHz), and memory 2 is set to a cycle time of 6.0 ns (333 MHz). Accordingly, 266 MHz, which is the lower of the two frequencies, is chosen as the common frequency. On the other hand, if a CL value of 2.5 is set as the common CAS latency, memory 1 is set to a cycle time of 6.0 ns (333 MHz), and memory 2 is set to a cycle time of 5.0 ns (400 MHz). Accordingly, a frequency of 333 MHz, which is the lower of the frequencies, is chosen as the common frequency in anticipation of better performance.

Referring to FIG. 6, CAS latency, cycle time, and frequency settings and results for two different memories according to an exemplary embodiment of the present invention are shown in (b). The method used in (b) of FIG. 6 is the same as the method of FIG. 4 except that each of the memories 1 and 2 supports three frequencies rather than two, and thus, the method of FIG. 4 can be used in (b) of FIG. 6. However, unlike the method of FIG. 4, both maximum and median frequencies supported by each of the memories 1 and 2 are taken into consideration when setting the common frequency, rather than considering only the maximum frequencies supported by each of memories 1 and 2. Referring to FIG. 6, the maximum frequency of memory 1 is 400 MHz (5.0 ns) which is equal to the maximum frequency supported by memory 2. Accordingly, 400 MHz is set as the common frequency for memories 1 and 2. Unlike the method of FIG. 4, in the method of (b) of FIG. 6, it is determined whether memories 1 and 2 have one or more CL values in common, rather than only one CL value as described above with reference to (a) of FIG. 6.

Once the common frequency for memories 1 and 2 is set to 400 MHz, memory 1 is set to a CL value of 3.0, and memory 2 is set to a CL value of 2.5. Accordingly, a CL value of 3.0, which is the higher of the two CL values, is chosen as the common CAS latency. As a result, the actual delay time is 15 ns because CAS latency is proportional to cycle time.

Therefore, the method shown in (b) of FIG. 6 achieves a higher operating speed but less actual delay time than the conventional method shown in (a) of FIG. 6.

FIG. 7 illustrates tables for comparing the performance of a method of setting the CAS latency and frequency for two heterogeneous memories according to an exemplary embodiment of the present invention with the performance of a conventional method. Referring to FIG. 7, CAS latencies, cycle times, and frequencies obtained using the conventional method and the method of setting CAS latency and frequency for two heterogeneous memories are shown in (a), and CAS latency, cycle time, and frequency setting results obtained using the method of setting CAS latency and frequency for two heterogeneous memories according to an exemplary embodiment of the present invention are shown in (b). Unlike FIG. 6, FIG. 7 shows maximum and median frequencies supported by memory 1 are the same as those supported by memory 2. In the conventional method shown in (a) of FIG. 7, if a CL value of 2.0 is set as a common CAS latency for memories 1 and 2, memory 1 is set to a cycle time of 7.5 ns (266 MHz), and memory 2 is set to a cycle time of 5.0 ns (333 MHz). Thus, a frequency of 266 MHz is chosen as a common frequency for memories 1 and 2. On the other hand, if a CL value of 2.5 is set as the common CAS latency, memory 1 is set to a cycle time of 6.0 ns, and memory 2 is set to a cycle time of 4.0 ns. Thus, a frequency of 333 MHz is chosen as a common frequency for memories 1 and 2.

The method shown in (b) of FIG. 7 produces different settings from the conventional method of (a) of FIG. 7. Specifically, in the method shown in (a) of FIG. 7, common cycle time is set ahead of a common CAS latency. The maximum frequency supported by memory 1 is not equal to the maximum frequency supported by memory 2, but the median frequency (400 MHz) is supported by both. Thus, 400 MHz is set as the common frequency for memories 1 and 2. As a result, memory 1 is set to a CL value of 3.0, and memory 2 is set to a CL value of 2.0. Thereafter, a CL value of 3.0, which is the highest CL value of the two memories, is set as the common CAS latency for memories 1 and 2. Accordingly, the method shown in (b) of FIG. 7 sets a CL value of 3.0 and a frequency of 400 MHz (5.0 ns) as the common CAS latency and the common frequency, respectively. Thus, the method shown in (b) of FIG. 7 achieves a higher common frequency but less actual delay time than the conventional method shown in (a) of FIG. 7.

FIG. 8 illustrates tables for comparing the performance of a method of setting the CAS latency and frequency for three different memories according to an exemplary embodiment of the present invention with the performance of a conventional method. Common CAS latency and common frequency settings obtained using the conventional method for two different memories are shown in (a) of FIG. 8. Referring to FIG. 8, memories 1, 2 and 3 have two CL values in common: 2.0 and 2.5. If a CL value of 2.0 is set as the common CAS latency for memories 1, 2, and 3, memory 1 is set to a cycle time of 7.5 ns (266 MHz), memory 2 is set to a cycle time of 6.0 ns (333 MHz), and memory 3 is set to a cycle time of 5.0 ns (400 MHz). Thereafter, a frequency of 266 MHz, which is the lowest frequency of memories 1, 2, and 3, is chosen as the common frequency. However, if a CL value of 2.5 is set as the common CAS latency, memory 1 is set to a cycle time of 6.0 ns (333 MHz), memory 2 is set to a cycle time of 5.0 ns (400 MHz), and memory 3 is set to a cycle time of 4.0 ns (500 MHz). Thereafter, 333 MHz, which is the lowest frequency of memories 1, 2, and 3, is chosen as the common frequency Referring to FIG. 8, CAS latency, cycle time, and frequency settings obtained using the method of setting the CAS latency and frequency for two different memories according to an exemplary embodiment of the present invention are shown in (b). Memories 1, 2, and 3 have two frequencies in common: 333 MHz and 400 MHz. Thus, a frequency of 400 MHz (5.0 ns), which is the highest frequency supported by all the memories, is set as the common frequency. As a result, memory 1 is set to a CL value of 3.0, memory 2 is set to a CL value of 2.5, and memory 3 is set to a CL value of 2.0. Thereafter, a CL value of 3.0, which is the highest CL value of the three memories, is chosen as the common CAS latency. Accordingly, a cycle time of 5.0 ns and a frequency of 400 MHz are chosen as common cycle time and a common frequency for memories 1, 2, and 3. Therefore, the method shown in (b) of FIG. 8 provides a higher common CAS latency than the conventional method shown in (a) of FIG. 8 but results in the same actual delay time as the conventional method. Thus, the method shown in (b) of FIG. 8 can provide the same actual delay time and a higher common frequency than the conventional method.

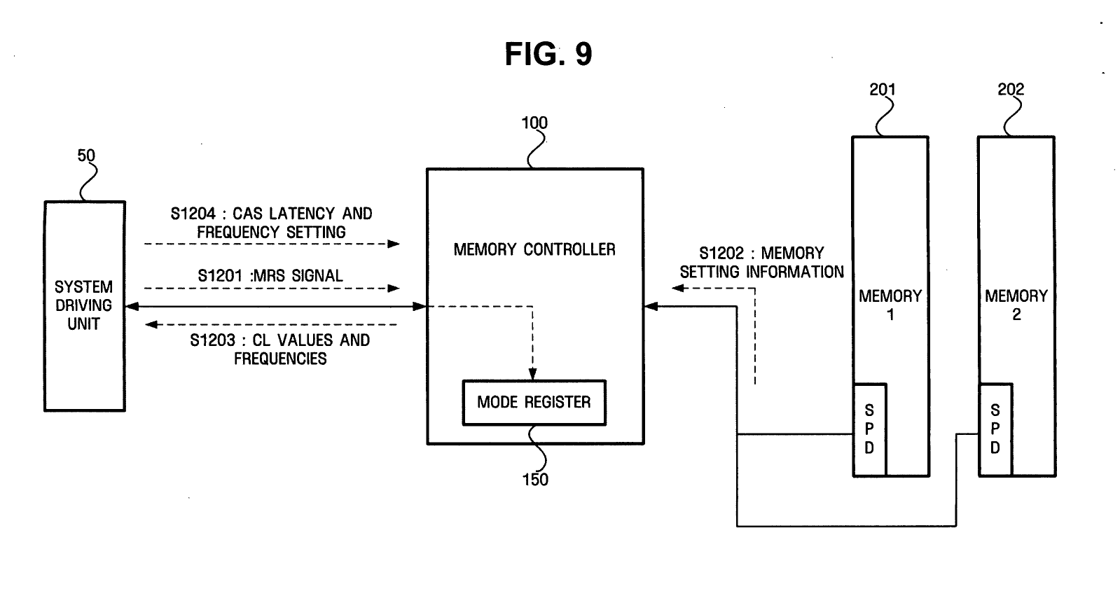

FIG. 9 is a block diagram illustrating an apparatus for setting the CAS latency and frequency heterogeneous memory according to an exemplary embodiment of the present invention.

Two memories are illustrated in FIG. 9, but the present invention is not restricted to this configuration. Referring to FIG. 9, a system driving unit 50 instructs a memory controller 100 to set memory information (operation S1201). When driving a system the system driving unit 50 first checks system resources and then system settings. The system driving unit 50 may be a BIOS if the system is a computer system or it may be an initial setting unit if the system is a set-top box. If the system is a computer system having a typical motherboard, the system driving unit 50 (e.g., a BIOS) may manage the transfer of SDP data to the memory controller 100 via a south bridge and a north bridge, which may differ from system to system depending on the structure of the motherboard or the type of module that serves a memory setting function.

The system driving unit 50 may be driven ahead of other components of the system when power is supplied to the system and it may control settings regarding the system. In addition, the system driving unit 50 may be a hardware device or a software program that manages the entire system or it may only manage the memory controller 100. If the system driving unit 50 instructs the memory controller 100 to perform mode register setting, the memory controller 100 reads information from memory 1 (201) and memory 2 (202) via a SPD bus (operation S1202). A SPD device, e.g., an EEPROM, may be coupled to memory 1 (201) and memory 2 (202). The information read from memory 1 (201) and memory 2 (202) comprises CL values and frequencies supported by memory 1 (201) and memory 2 (202). The memory controller 100 transmits the information read from memory 1 (201) and memory 2 (202) to the system driving unit 50 (operation S1203). Then, the system driving unit 50 chooses an optimum CL value and an optimum frequency from among the CL values and frequencies supported by memories 1 (201) and memory 2 (202) according to the flowchart of FIG. 4. Thereafter, the system driving unit 50 stores the optimum CL value and the optimum frequency in a mode register 150 (operation S1204). Then, the memory controller 100 performs a write or read operation on memory 1 (201) or memory 2 (202) using the optimum CL value and the optimum frequency stored in the mode register 50.

As described above, according to embodiments of the present invention, it is possible for a system using two or more different memories to effectively drive the memories at full capacity. In addition, it is possible to extend the memories without degrading memory performance.

It will be understood by those of ordinary skill in the art that various changes in form and details may be made therein without departing from the spirit and scope of the present invention as defined by the following claims. Therefore, the above described exemplary embodiments are for purposes of illustration only and are not to be construed as limiting the invention. The scope of the invention is given by the appended claims, rather than the preceding description, and all variations and equivalents which fall within the range of the claims are intended to be embraced therein.

What is claimed is:

1. A method of setting column address strobe (CAS) latency and frequency of heterogeneous memories comprising:
obtaining setting information related to CAS latencies and frequencies supported by two or more memories; and
comparing the CAS latencies supported by the memories and setting a highest frequency from among the common frequencies as a common frequency for the memories if the memories have one or more CAS latencies in common.

2. The method of claim 1 further comprising setting a highest CAS latency value from among the common CAS latency values as a common CAS latency for the memories after the setting of the common frequency.

3. The method of claim 2, wherein the setting information is stored in non-volatile storage devices coupled to each of the memories.

4. The method of claim 2, wherein the common frequency and the common CAS latency are stored in a memory controller.

5. The method of claim 1, wherein at least one of the memories is a dual in-line memory module (DIMM).

6. The method of claim 1, wherein at least one of the memories is a double data rate (DDR) synchronous dynamic random access memory (SDRAM).

7. The method of claim 1, further comprising:
recording a storage capacity, operating speed, voltage, and the number of address columns and rows of the two or more memories.

8. A system comprising:
two or more memories for storing information from which data is written and read, respectively;
a system driving unit for managing a setting for the memories; and
a memory controller for controlling the memories,
wherein if the memories have one or more column address strobe (CAS) latencies in common, the system driving unit sets a highest frequency from among the common frequencies as a common frequency for the memories, and the memory controller controls the memories to operate at this common frequency.

9. The system of claim 8, wherein the system driving unit sets a highest CAS latency value among the common CAS latency values as a common CAS latency for the memories, and the memory controller controls the memories to operate at this common CAS latency.

10. The system of claim 9, wherein CAS latencies and frequencies supported by each of the memories are stored in a non-volatile storage device that is coupled to the memories.

11. The system of claim 9, wherein the memory controller comprises a control information storage unit that stores the common frequency and the common CAS latency.

12. The system of claim 8, wherein the system driving unit is a basic input output system (BIOS).

13. The system of claim 8, wherein the system comprises a computer system.

14. The system of claims 8, wherein one of the memories is a dual in-line memory module (DIMM).

15. The system of claim 8, wherein at least one of the memories is a double data rate (DDR) synchronous dynamic random access memory (SDRAM).

16. The system of claim 8, further comprising:
a Serial Presence Detect (SPD) Device for recording a storage capacity, operating speed, voltage, and the number of address columns and rows of the two or more memories.

17. A recording medium having a computer readable program recorded therein with instructions for setting a column address strobe (CAS) latency and frequency of heterogeneous memories, comprising:
a first set of instructions for obtaining setting information related to CAS latencies and frequencies supported by two or more memories; and
a second set of instructions for comparing the CAS latencies supported by the memories and setting a highest frequency from among the common frequencies as a common frequency for the memories if the memories have one or more CAS latencies in common.
